(19) United States
(12) Patent Application Publication
(10) Pub. No.: US 2026/0362864 A1
(43) Pub. Date: Nov. 12, 2026

(54) OPTICAL PACKAGE AND METHOD FOR MANUFACTURING THE SAME

(71) Applicant: Ennostar Corporation, Hsinchu City (TW)

(72) Inventors: Shiou-Yi KUO, Hsinchu City (TW); Ching-Yi CHEN, Hsinchu City (TW)

(21) Appl. No.: 19/668,677

(22) Filed: May 5, 2026

(30) Foreign Application Priority Data
May 9, 2025 (TW) 114117459

(51) Int. Cl. H10H 20/851; H10H 20/01; H10H 20/841

(52) U.S. Cl. CPC H10H 20/8515; H10H 20/034; H10H 20/0361; H10H 20/841; H10H 20/021

(57) ABSTRACT

An optical package is provided. The optical package includes a light-emitting element, a wavelength conversion layer, and an adhesive layer. The wavelength conversion layer is disposed on the light-emitting element. The adhesive layer is disposed between the light-emitting element and the wavelength conversion layer. The adhesive layer is in contact with the light-emitting element and the wavelength conversion layer. Moreover, the thickness of the wavelength conversion layer is greater than the thickness of the light-emitting element.

### CROSS REFERENCE TO RELATED APPLICATIONS

This application claims the benefit of Taiwan Application No. 114117459, filed May. 9, 2025, the entirety of which is incorporated by reference herein.

### BACKGROUND

### Technical Field

The present disclosure is related to an optical package, and in particular, it is related to an optical package with improved packaging efficiency.

### Description of the Related Art

Light-emitting diodes (LEDs) are light-emitting elements that are widely used as light sources in various electronic devices. With the increasing integration and application of electronic devices, consumers have increasingly higher expectations for such devices.

To meet the demand for high resolution and achieve higher production throughput, the size of LEDs has been continuously reduced. However, such miniaturization presents numerous unresolved challenges in the manufacturing process, which in turn can affect the performance of these light-emitting elements. For example, conventional LEDs that use a sapphire substrate as the light-emitting surface suffer from a wide light emission angle and limitations in incorporating light modulation structures into the packaging. These issues result in severe cross-talk between LED pixels, thereby degrading optical quality.

Accordingly, how to further improve the optical packaging structure of LEDs to enhance the performance of electronic devices remains one of the most important research topics currently being studied in the industry.

### SUMMARY

In accordance with some embodiments of the present disclosure, an optical package is provided. The optical package includes a light-emitting element, a wavelength conversion layer, and an adhesive layer. The wavelength conversion layer is disposed on the light-emitting element. The adhesive layer is disposed between the light-emitting element and the wavelength conversion layer. The adhesive layer is in contact with the light-emitting element and the wavelength conversion layer. The thickness of the wavelength conversion layer is greater than the thickness of the light-emitting element.

In order to make the features and advantages of the present disclosure more readily understood, several embodiments are described in detail below with reference to the accompanying drawings.

### BRIEF DESCRIPTION OF THE DRAWINGS

The present disclosure may be more fully understood by reading the subsequent detailed description and examples with references made to the accompanying drawings, wherein:

FIGS. 1A-1J are cross-sectional schematic diagrams illustrating an optical package at various stages of a manufacturing process in accordance with some embodiments of the present disclosure;

FIG. 2 is a cross-sectional schematic diagram illustrating an optical package in accordance with some embodiments of the present disclosure;

FIGS. 3A and 3B are cross-sectional schematic diagrams illustrating an optical package in accordance with some embodiments of the present disclosure;

FIGS. 4A and 4B are cross-sectional schematic diagrams illustrating an optical package in accordance with some embodiments of the present disclosure;

FIGS. 5A and 5B are cross-sectional schematic diagrams illustrating an optical package in accordance with some embodiments of the present disclosure;

FIG. 6 is a cross-sectional schematic diagram illustrating an optical package in accordance with some embodiments of the present disclosure;

FIG. 7 is a cross-sectional schematic diagram illustrating an optical package in accordance with some embodiments of the present disclosure;

FIG. 8 is a top-view schematic diagram illustrating an electronic device including an optical package in accordance with some embodiments of the present disclosure.

### DETAILED DESCRIPTION

The optical packages and method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may not be drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers “first”, “second”, etc. mentioned in the specification or claims of the present application are used to name different elements or to distinguish different embodiments or scopes. They are not used to limit the upper or lower limit of the number of elements, nor are they used to limit the manufacturing sequence or disposing sequence of the elements. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “disposed”, “connected with/to”, etc. referring to bonding and connection, unless specifically defined, these terms mean that two structures are in direct contact or two structures are not in direct contact, and other structures are provided to be disposed between the two structures. The terms for disposing and connecting may also include the case where both structures are movable or both structures are fixed.

In the following descriptions, terms “about”, “substantially” and “approximately” typically mean +/- 10% of the stated value, or typically +/- 5% of the stated value, or typically +/- 3% of the stated value, or typically +/- 2% of the stated value, or typically +/- 1% of the stated value or typically +/- 0.5% of the stated value. The expression “in a range greater than or equal to the first value and less than or equal to the second value” or “in a range between the first value and the second value” means that the range includes the first value, the second value, and other values in between.

Unless defined otherwise, all technical and scientific terms used herein have the same meaning as commonly understood by one of ordinary skill in the art to which the present disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, the provided method for manufacturing an optical package employs a laser lift-off (LLO) process and an adhesive bonding process to bond a light-emitting element with a wavelength conversion layer. Through such a configuration, the light-emitting element and the wavelength conversion layer may be joined without a substrate structure (e.g., a sapphire substrate) therebetween. This can improve the packaging efficiency of the light-emitting element and effectively enhance the optical performance of the optical package.

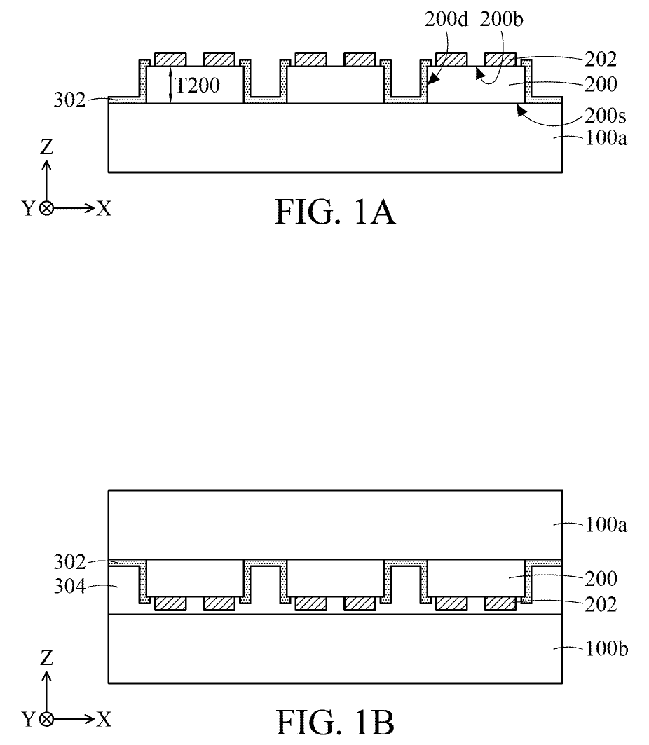

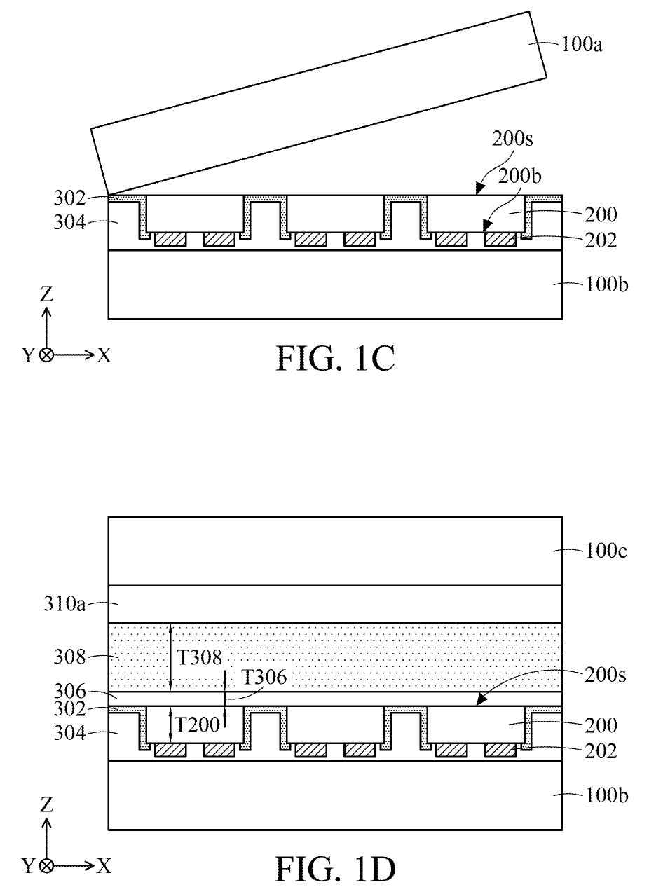

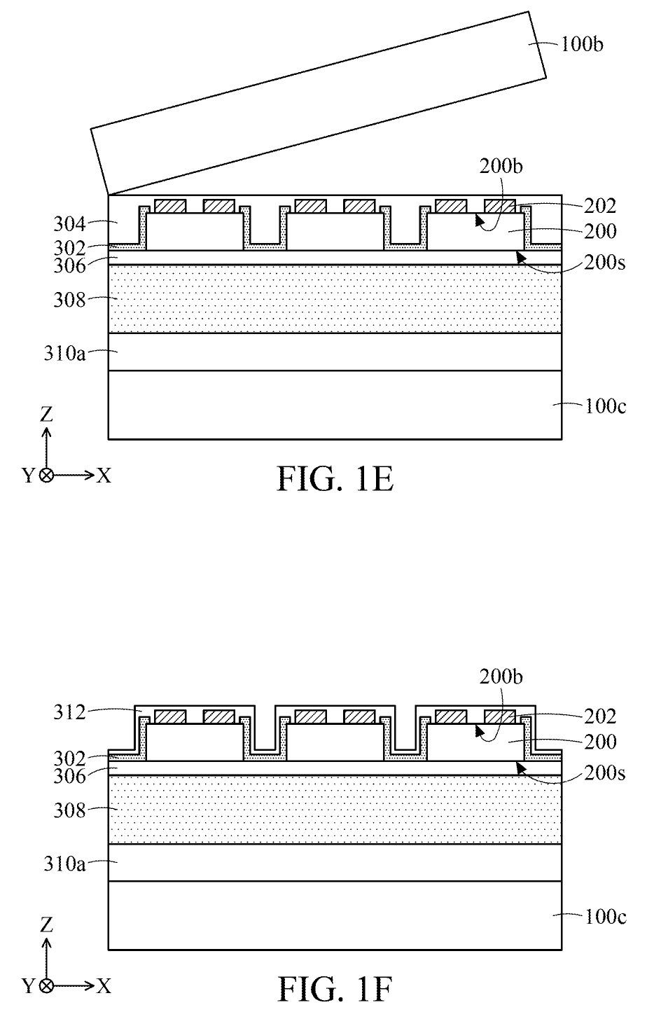

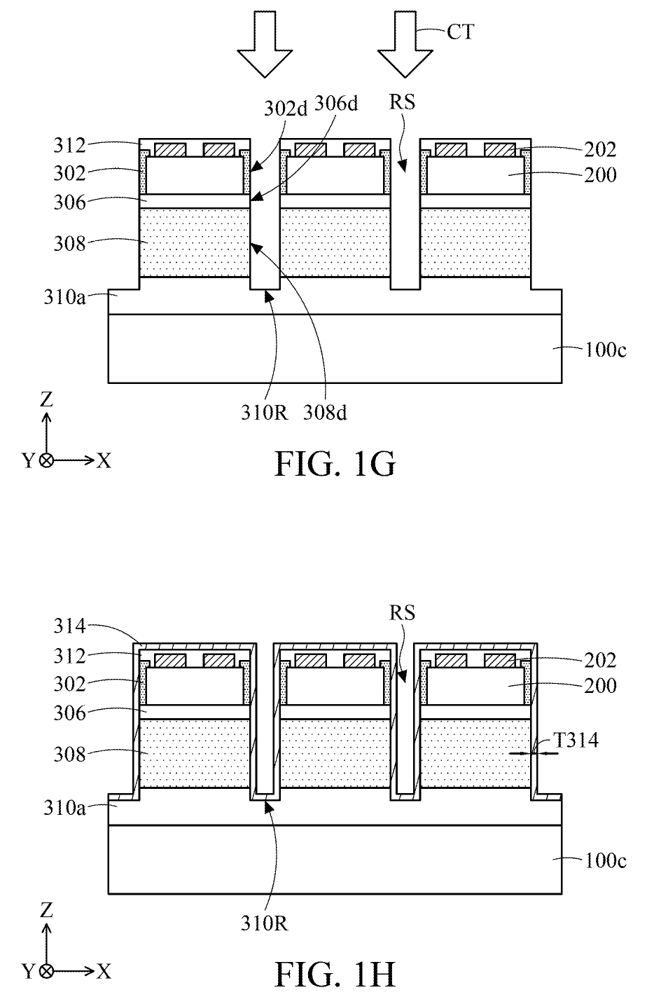

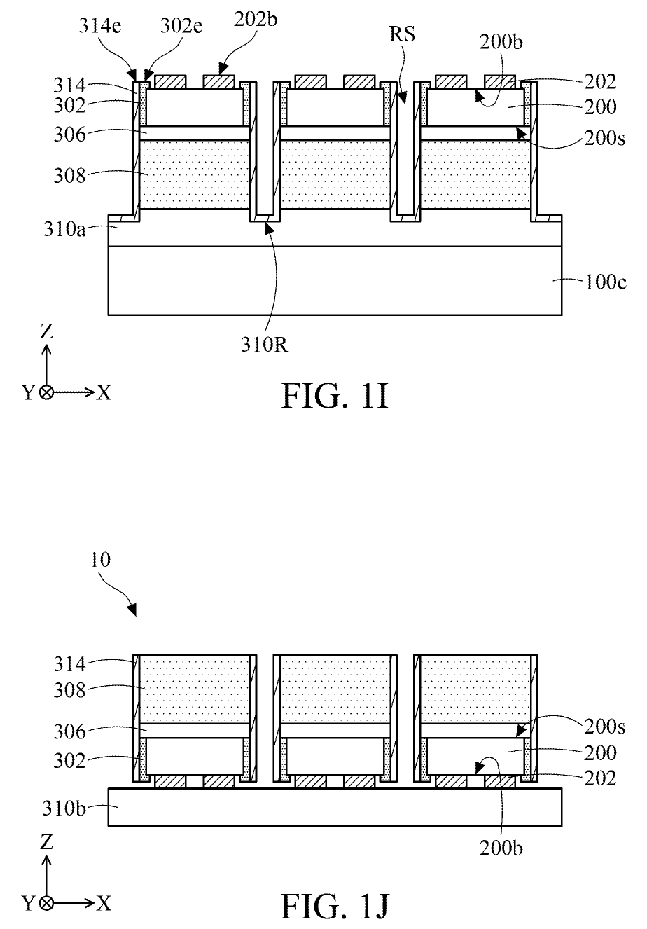

Please refer to FIGS. 1A-1J, which are cross-sectional schematic diagrams illustrating an optical package at various stages of a manufacturing process in accordance with some embodiments of the present disclosure. It should be understood that, in accordance with some embodiments, additional operation steps may be provided before, during, and/or after the method of manufacturing the optical package. In accordance with some embodiments, some of the operation steps described may be replaced or omitted, and the order of some of the operation steps described may be interchangeable.

Referring first to FIG. 1A, a first substrate 100a is provided, and a light-emitting element 200 is formed on the first substrate 100a. The light-emitting element 200 may include a first surface 200b that faces away from the first substrate 100a and a second surface 200s opposite the first surface 200b.

Referring to FIG. 1A, in accordance with some embodiments, the first substrate 100a may include a sapphire substrate, a silicon carbide substrate, a glass substrate, a quartz substrate, other suitable substrates, or a combination thereof, but it is not limited thereto.

Referring to FIG. 1A, the light-emitting element 200 may be a light-emitting diode, such as a mini light-emitting diode (mini LED) or a micro light-emitting diode (micro LED). The light-emitting element 200 may be a thin-film light-emitting diode (thin-film LED). Specifically, in accordance with some embodiments, the thickness T200 of the light-emitting element 200 may be in a range from about 3 micrometers to about 20 micrometers, such as 3 μm, 5 μm, 10 μm, 15 μm, 17 μm, or 20 μm. In accordance with some embodiments, the thickness T200 may be in a range from about 5 μm to about 17 μm. In some other embodiments, the thickness T200 may be in a range from about 10 μm to about 15 μm. Furthermore, the light-emitting element 200 may emit white light, blue light, red light, green light, or other suitable colors of light. In accordance with some embodiments, the light-emitting element 200 may be a flip-chip light-emitting diode.

Referring to FIG. 1A, in detail, the light-emitting element 200 may include a first-type semiconductor layer (not shown, e.g., an N-type doped semiconductor layer), a second-type semiconductor layer (not shown, e.g., a P-type doped semiconductor layer), and a light-emitting layer (not shown) disposed between the first-type semiconductor layer and the second-type semiconductor layer. In other words, the light-emitting element 200 may be a PN-junction diode, but the present disclosure is not limited thereto. In accordance with some embodiments, the light-emitting element 200 may emit blue light. In accordance with some embodiments, the light-emitting element 200 may be formed on the first substrate 100a through an epitaxial growth process.

Referring to FIG. 1A, furthermore, the light-emitting element 200 may include an electrode 202 disposed on the first surface 200b of the light-emitting element 200. The electrode 202 may electrically connect the light-emitting element 200 to other conductive components. The electrode 202 may include a metal conductive material, a transparent conductive material, or other suitable conductive materials. In accordance with some embodiments, the metal conductive material may include copper (Cu), aluminum (Al), tungsten (W), titanium (Ti), gold (Au), platinum (Pt), nickel (Ni), tin (Sn), indium (In), or alloys thereof such as copper alloy, aluminum alloy, tungsten alloy, titanium alloy, gold alloy, platinum alloy, nickel alloy, tin alloy, indium alloy, other suitable conductive materials, or a combination thereof, but it is not limited thereto. The transparent conductive material may include transparent conductive oxides (TCOs), such as indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive materials, or a combination thereof, but it is not limited thereto. The electrode 202 may be formed by chemical vapor deposition (CVD), physical vapor deposition (PVD), electroplating, electroless plating, or other suitable processes, or a combination thereof. The CVD processes may include, for example, low-pressure chemical vapor deposition (LPCVD), low-temperature chemical vapor deposition (LTCVD), rapid thermal chemical vapor deposition (RTCVD), plasma-enhanced chemical vapor deposition (PECVD), or atomic layer deposition (ALD), but are not limited thereto. The PVD processes may include, for example, sputtering, evaporation, pulsed laser deposition, or the like. In addition, the electrode 202 may be patterned by one or more photolithography processes and/or etching processes.

Referring to FIG. 1A, moreover, in accordance with some embodiments, a passivation layer 302 may be formed on the first substrate 100a and the light-emitting element 200. The passivation layer 302 may cover the side surface 200d and the first surface 200b of the light-emitting element 200. In detail, the passivation layer 302 may be conformally formed on portions of the first surface 200b and side surface 200d of the light-emitting element 200, as well as on the first substrate 100a. In accordance with some embodiments, the passivation layer 302 is not in contact with the electrode 202; that is, while the passivation layer 302 extends over the first surface 200b, it is spaced apart from the electrode 202 without direct contact. In accordance with other embodiments, the passivation layer 302 may extend over the first surface 200b and be in contact with the electrode 202.

Referring to FIG. 1A, in accordance with some embodiments, the passivation layer 302 may have a single-layer or multi-layer structure, and may be formed of inorganic materials, organic materials, or a combination thereof, but it is not limited thereto. For example, the inorganic material may include silicon nitride, silicon oxide, silicon oxynitride, another suitable material, or a combination thereof. The organic material may include polyethylene terephthalate (PET), polyethylene (PE), polyethersulfone (PES), polycarbonate (PC), polymethyl methacrylate (PMMA), polyimide (PI), other suitable materials, or a combination thereof, but it is not limited thereto. The passivation layer 302 may be formed by coating processes, chemical vapor deposition, physical vapor deposition, atomic layer deposition, printing processes, or other suitable processes, or a combination thereof. Moreover, the passivation layer 302 may be patterned using one or more photolithography processes and/or etching processes. In accordance with some embodiments, the passivation layer 302 may be a distributed Bragg reflector (DBR). In accordance with some embodiments, the DBR may include thin films composed of two or more materials with different refractive indices, stacked in a homogeneous or heterogeneous manner. For example, the DBR may be formed by alternating layers of silicon dioxide (SiO₂) and titanium dioxide (TiO₂), by alternating layers of silicon dioxide (SiO₂)/aluminum oxide (Al₂O₃)/titanium dioxide (TiO₂), or by alternating layers of titanium dioxide (TiO₂)/silicon dioxide (SiO₂)/tantalum pentoxide (Ta₂O₅).

Please refer to FIG. 1B. The aforementioned structure may then be flipped and bonded to a second substrate 100b via an adhesive layer 304. For example, the light-emitting element 200 may be disposed adjacent to the first substrate 100a and the electrode 202 may be disposed adjacent to the second substrate 100b. The adhesive layer 304 may be formed between the first substrate 100a and the second substrate 100b and may cover the light-emitting element 200, the electrode 202, and the passivation layer 302.

Referring to FIG. 1B, the second substrate 100b may serve as a temporary carrier substrate. In accordance with some embodiments, the material of the second substrate 100b may include glass, quartz, sapphire, ceramic, other suitable materials, or a combination thereof, but the present disclosure is not limited thereto. In accordance with some embodiments, the second substrate 100b may include polycarbonate (PC), polyimide (PI), polyethylene terephthalate (PET), polypropylene (PP), other suitable materials, or a combination thereof, but the present disclosure is not limited thereto. In accordance with some embodiments, the second substrate 100b may include rubber, fiberglass, other suitable materials, or a combination thereof, but it is not limited thereto.

Referring to FIG. 1B, in accordance with some embodiments, the second substrate 100b may be or include Group III-V compounds (e.g., gallium nitride (GaN), gallium arsenide (GaAs), gallium phosphide (GaP), aluminum gallium arsenide (AlGaAs), aluminum nitride (AlN), aluminum gallium nitride (AlGaN)), Group IV elements or Group IV compounds (e.g., silicon (Si), silicon carbide (SiC), diamond (C)), other suitable materials or a combination thereof, but the present disclosure is not limited thereto. In accordance with some embodiments, the second substrate 100b may be or include a flexible substrate, a bendable substrate, a rigid substrate, or a combination thereof, but the present disclosure is not limited thereto. For example, the second substrate 100b may be a sapphire substrate. In accordance with some embodiments, the second substrate 100b may be or include a transparent substrate, a semi-transparent substrate, or an opaque substrate, but the present disclosure is not limited thereto.

Referring to FIG. 1B, in accordance with some embodiments, the adhesive layer 304 may include a photo-curing adhesive material, a thermo-curing adhesive material, a photothermal-curing adhesive material, other suitable adhesive material, or a combination thereof, but it is not limited thereto. In accordance with some embodiments, the material of the adhesive layer 304 may include optical clear adhesive (OCA), optical clear resin (OCR), other suitable materials, or a combination thereof, but it is not limited thereto. In accordance with some embodiments, the adhesive layer 304 may include silicone. In accordance with some embodiments, the adhesive layer 304 may be formed by coating, printing, lamination, other suitable processes, or a combination thereof.

Please refer to FIG. 1C. The first substrate 100a may then be removed. After removing the first substrate 100a, the second surface 200s of the light-emitting element 200 and a portion of the passivation layer 302 may be exposed. In accordance with some embodiments, the exposed second surface 200s of the light-emitting element 200 and the passivation layer 302 may be coplanar with each other.

Referring to FIG. 1C, in accordance with some embodiments, the first substrate 100a may be separated from the light-emitting element 200 and the passivation layer 302 through a laser lift-off (LLO) process. In accordance with some embodiments, the second surface 200s of the light-emitting element 200 serves as the light-emitting surface. In accordance with some embodiments, the second surface 200s of the light-emitting element 200 is flat. In accordance with some embodiments, the second surface 200s of the light-emitting element 200 has a roughened texture. In accordance with some embodiments, the second surface 200s of the light-emitting element 200 has a uniformly roughened texture, such as circular or hexagonal concave surfaces to enhance light extraction. In accordance with some embodiments, the light-emitting element 200 has the second surface 200s with periodically arranged concave-convex patterns. In accordance with some embodiments, the first substrate 100a is a patterned sapphire substrate (PSS), and the light-emitting element 200 itself does not include the first substrate 100a such as PSS, but the second surface 200s exhibits periodic protrusions and recesses resulting from the LLO removal of the first substrate 100a.

Please refer to FIG. 1D. An adhesive layer 306 may then be formed on the second surface 200s of the light-emitting element 200, and a wavelength conversion layer 308 may be formed on the second surface 200s of the light-emitting element 200. The adhesive layer 306 may be disposed between the light-emitting element 200 and the wavelength conversion layer 308 and may be in contact with both the light-emitting element 200 and the wavelength conversion layer 308, so that the light-emitting element 200 and the wavelength conversion layer 308 are bonded together. In accordance with some embodiments, the adhesive layer 306 may be disposed between the light-emitting element 200 and the wavelength conversion layer 308 and directly contact the light-emitting element 200 and the wavelength conversion layer 308.

Referring to FIG. 1D, the adhesive layer 306 may include photocurable adhesive, thermosetting adhesive, photo-thermal curing adhesive, other suitable adhesives, or a combination thereof, but it is not limited thereto. In accordance with some embodiments, the material of the adhesive layer 306 may include optical clear adhesive (OCA), optical clear resin (OCR), other suitable materials, or a combination thereof, but it is not limited thereto. In accordance with some embodiments, the adhesive layer 306 may include silicone. In accordance with some embodiments, the adhesive layer 306 may be formed by coating, printing, lamination, other suitable processes, or a combination thereof.

Referring to FIG. 1D, in accordance with some embodiments, the thickness T306 of the adhesive layer 306 may be in a range from 1 μm to 3 μm, such as 1.5 μm, 2 μm, or 2.5 μm.

Referring to FIG. 1D, the wavelength conversion layer 308 may convert the light generated by the light-emitting element 200 into light of a specific color or wavelength. The wavelength conversion layer 308 may include a matrix and one or more wavelength conversion materials dispersed within the matrix. In accordance with some embodiments, the matrix may include glass or polymer materials, but it is not limited thereto. In accordance with some embodiments, the wavelength conversion materials may include phosphors, quantum dot materials, or a combination thereof, but it is not limited thereto. Further, in accordance with some embodiments, the light-emitting element 200 may be a light-emitting diode that emits blue light, and the wavelength conversion layer 308 may include yellow phosphor. For example, the yellow phosphor may be yttrium aluminum garnet (YAG) phosphor, such that the optical package may emit white light, but the present disclosure is not limited thereto. In accordance with some embodiments, the wavelength conversion layer 308 may include red phosphor, green phosphor, other suitable colored phosphors, or a combination thereof, but it is not limited thereto. In accordance with some embodiments, the wavelength conversion layer 308 may include two different red phosphors, green phosphor, other suitable colored phosphors, or a combination thereof, but it is not limited thereto. In accordance with some embodiments, the wavelength conversion layer 308 may include green phosphor and red phosphor. For example, the wavelength conversion layer 308 may include green SiAlON phosphor and red K2SiF6:Mn⁴⁺. In accordance with some embodiments, the wavelength conversion layer 308 may include a combination of green phosphor and two types of red phosphors, for example, may include green SiAlON phosphor, red K2SiF6:Mn⁴⁺, and red (Sr,Ca)AlSiN₃:Eu²⁺. Moreover, in accordance with some embodiments, the wavelength conversion layer 308 may be a phosphor in glass (PiG) composite material. For example, a suitable phosphor powder may be sintered in glass to form the phosphor in glass composite material.

Referring to FIG. 1D, furthermore, the thickness T308 of the wavelength conversion layer 308 may be greater than the thickness T200 of the light-emitting element 200. Specifically, the thickness T308 of the wavelength conversion layer 308 may be in a range from 60 μm to 200 μm, such as 70 μm, 80 μm, 90 μm, 100 μm, 110 μm, 120 μm, 130 μm, 140 μm, 150 μm, 160 μm, 170 μm, 180 μm, or 190 μm. In accordance with some embodiments, the thickness T308 of the wavelength conversion layer 308 may be in a range from 80 μm to 180 μm. In accordance with some embodiments, the thickness T308 of the wavelength conversion layer 308 may be in a range from 100 μm to 160 μm. In accordance with some embodiments, the thickness T308 of the wavelength conversion layer 308 may be in a range from 120 μm to 150 μm.

As shown in FIG. 1D, an adhesive layer 310a may further be formed on the wavelength conversion layer 308, and a third substrate 100c may be provided and formed on the adhesive layer 310a. The adhesive layer 310a may bond the wavelength conversion layer 308 to the third substrate 100c. In other words, the third substrate 100c may be fixed to the wavelength conversion layer 308 via the adhesive layer 310a.

As shown in FIG. 1D, the third substrate 100c may serve as a temporary carrier substrate. In accordance with some embodiments, the material of the third substrate 100c may include glass, quartz, sapphire, ceramic, other suitable materials, or a combination thereof, but the present disclosure is not limited thereto. In accordance with some embodiments, the third substrate 100c may include polycarbonate (PC), polyimide (PI), polyethylene terephthalate (PET), polypropylene (PP), other suitable materials, or a combination thereof, but it is not limited thereto. In accordance with some embodiments, the third substrate 100c may include rubber, fiberglass, other suitable materials, or a combination thereof, but it is not limited thereto. In accordance with some embodiments, the third substrate 100c may be or include Group III-V compounds (e.g., GaN, GaAs, GaP, AlGaAs, AlN, AlGaN), Group IV elements or Group IV compounds (e.g., Si, SiC, C), other suitable materials or a combination thereof, but the present disclosure is not limited thereto. In accordance with some embodiments, the third substrate 100c may be or include a flexible substrate, a bendable substrate, a rigid substrate, or a combination thereof, but it is not limited thereto. For example, the third substrate 100c may be a sapphire substrate. In accordance with some embodiments, the third substrate 100c may be or include a transparent substrate, a semi-transparent substrate, or an opaque substrate, but the present disclosure is not limited thereto.

As shown in FIG. 1D, furthermore, the adhesive layer 310a may include a light-curing adhesive, a heat-curing adhesive, a light-heat-curing adhesive, or a combination thereof, but it is not limited thereto. In accordance with some embodiments, the material of the adhesive layer 310a may include optical clear adhesive (OCA), optical clear resin (OCR), another suitable material, or a combination thereof, but it is not limited thereto. In accordance with some embodiments, the adhesive layer 310a may be formed by coating, printing, lamination, other suitable processes, or a combination thereof.

Please refer to FIG. 1E. The second substrate 100b may then be removed. After removing the second substrate 100b, the adhesive layer 304 may be exposed.

As shown in FIG. 1E, in accordance with some embodiments, the second substrate 100b may be separated from the adhesive layer 304 through a laser lift-off (LLO) process.

As shown in FIG. 1F, the adhesive layer 304 may then be removed, and a photoresist layer 312 may be formed to cover the first surface 200b. The photoresist layer 312 may also cover the electrode 202 and the passivation layer 302.

As shown in FIG. 1F, in accordance with some embodiments, the adhesive layer 304 may be removed by a chemical etching process (e.g., dry or wet etching), laser lift-off (LLO), laser bombardment, or other suitable processes or a combination thereof.

As shown in FIG. 1F, furthermore, the photoresist layer 312 may include any suitable photoresist material. In accordance with some embodiments, the photoresist layer 312 may be formed by chemical vapor deposition (CVD), physical vapor deposition (PVD), coating, printing, other suitable processes, or a combination thereof.

As shown in FIG. 1G, a cutting step CT may then be performed to cut the photoresist layer 312, the passivation layer 302, the adhesive layer 306, the wavelength conversion layer 308, and the adhesive layer 310a, such that the side surface 308d of the wavelength conversion layer 308, the side surface 306d of the adhesive layer 306, and the side surface 302d of the passivation layer 302 are aligned. Specifically, the cutting step CT may cut through the photoresist layer 312, the passivation layer 302, the adhesive layer 306, and the wavelength conversion layer 308, and may also partially cut the adhesive layer 310a. In accordance with some embodiments, the cutting step CT may form a recess RS, which extends from the photoresist layer 312 into the adhesive layer 310a. In accordance with some embodiments, a recessed profile 310R may be formed in the adhesive layer 310a during the cutting step CT.

As shown in FIG. 1G, in accordance with some embodiments, the cutting step CT may include a blade dicing process, for example, using a diamond blade, but it is not limited thereto. In accordance with some embodiments, the cutting step CT may be performed using a blade, laser, plasma dicing, other suitable methods or tools, or a combination thereof.

Please refer to FIG. 1H. A light-modulating structure 314 may then be formed to surround the light-emitting element 200, the wavelength conversion layer 308, and the adhesive layer 306, and the light-modulating structure 314 may be in contact with the wavelength conversion layer 308 and the adhesive layer 306. In accordance with some embodiments, the light-modulating structure 314 may be in direct contact with both the wavelength conversion layer 308 and the adhesive layer 306. Specifically, the light-modulating structure 314 may be conformally formed over the photoresist layer 312 and within the recess RS. In addition to the wavelength conversion layer 308 and adhesive layer 306, the light-modulating structure 314 may also contact the photoresist layer 312, the passivation layer 302, and the adhesive layer 310a.

As shown in FIG. 1H, the light-modulating structure 314 may have a single-layer or multi-layer structure. The light-modulating structure 314 may have high reflectivity, for example, a reflectivity greater than 90%, such as 91%, 92%, 93%, 94%, 95%, 96%, 97%, 98%, 99%, or 100%. In accordance with some embodiments, the light-modulating structure 314 may include a matrix and a high-reflectivity material disposed on the surface of the matrix or within the matrix. The matrix may include organic materials such as epoxy resin, acrylic resin such as polymethylmetacrylate (PMMA), benzocyclobutene (BCB), polyimide, polyester, polydimethylsiloxane (PDMS), polyethylene terephthalate (PET), polycarbonate (PC), or other suitable materials or a combination thereof, but it is not limited thereto. In accordance with some embodiments, the matrix may include glass. In accordance with some embodiments, the high-reflectivity material may include silver (Ag), aluminum (Al), titanium (Ti), titanium dioxide (TiO₂), or other suitable materials or a combination thereof, but it is not limited thereto. In accordance with some embodiments, the high-reflectivity material may include heat-curing high-reflectivity silicone, but it is not limited thereto. In accordance with some other embodiments, the light-modulating structure 314 may include an omni-directional reflector (ODR) structure, a distributed Bragg reflector (DBR) structure, or a combination thereof. In accordance with some embodiments, the light-modulating structure 314 may partially reflect and partially transmit light. Furthermore, in accordance with some embodiments, the material of the light-modulating structure 314 may include metals such as indium (In), tin (Sn), aluminum (Al), gold (Au), platinum (Pt), zinc (Zn), silver (Ag), titanium (Ti), germanium (Ge), copper (Cu), nickel (Ni), gold-beryllium (AuBe), gold-germanium (AuGe), gold-zinc (AuZn), lead-tin (PbSn), other highly reflective metals, or a combination thereof, but it is not limited thereto. In accordance with some embodiments, the light-modulating structure 314 may be formed by chemical vapor deposition, physical vapor deposition, printing, coating, or other suitable processes or a combination thereof.

As shown in FIG. 1H, furthermore, the thickness T314 of the light-modulating structure 314 may be less than 1 μm, for example, 0.9 μm, 0.8 μm, 0.7 μm, 0.6 μm, 0.5 μm, 0.4 μm, 0.3 μm, 0.2 μm, or 0.1 μm.

Please refer to FIG. 1I. The photoresist layer 312 may then be removed to expose the first surface 200b of the light-emitting element 200 and the electrode 202. Specifically, after forming the light-modulating structure 314, the photoresist layer 312 and the portion of the light-modulating structure 314 formed thereon may be removed, leaving only the light-modulating structure 314 in the recess RS. In accordance with some embodiments, after removing the photoresist layer 312, an end portion 314e of the light-modulating structure 314 may be aligned with an end portion 302e of the passivation layer 302. In accordance with some embodiments, the end portion 314e of the light-modulating structure 314 may not be aligned with the first surface 200b of the light-emitting element 200. For example, the end portion 314e of the light-modulating structure 314 may protrude beyond the first surface 200b. In accordance with some embodiments, along the normal direction of the light-emitting element 200 (e.g., the Z direction in the drawing), the end portion 314e of the light-modulating structure 314 may be located between the first surface 200b of the light-emitting element 200 and the surface 202b of the electrode 202, and the surface 202b of the electrode 202 may be a surface facing away from the light-emitting element 200.

As shown in FIG. 1I, in accordance with some embodiments, the photoresist layer 312 may be removed by stripping, ashing, or other suitable methods.

Please refer to FIG. 1J. The structure may then be flipped and transferred onto an adhesive layer 310b. For example, the electrode 202 may be bonded to the adhesive layer 310b, and the adhesive layer 310a and the third substrate 100c may be removed to expose the wavelength conversion layer 308. In accordance with some embodiments, the exposed surface of the wavelength conversion layer 308 may be coplanar with the light-modulating structure 314. In accordance with some embodiments, the adhesive layer 310b may be a UV tape.

As shown in FIG. 1J, in accordance with some embodiments, the adhesive layer 310a and the third substrate 100c may be removed by chemical etching (e.g., dry or wet etching), laser lift-off (LLO), laser bombardment, or other suitable processes or a combination thereof.

As shown in FIG. 1J, at this point, the manufacturing process of the optical package 10 is substantially completed. In accordance with some embodiments, the optical package 10 may be removed from the adhesive layer 310b through UV debonding for subsequent processing.

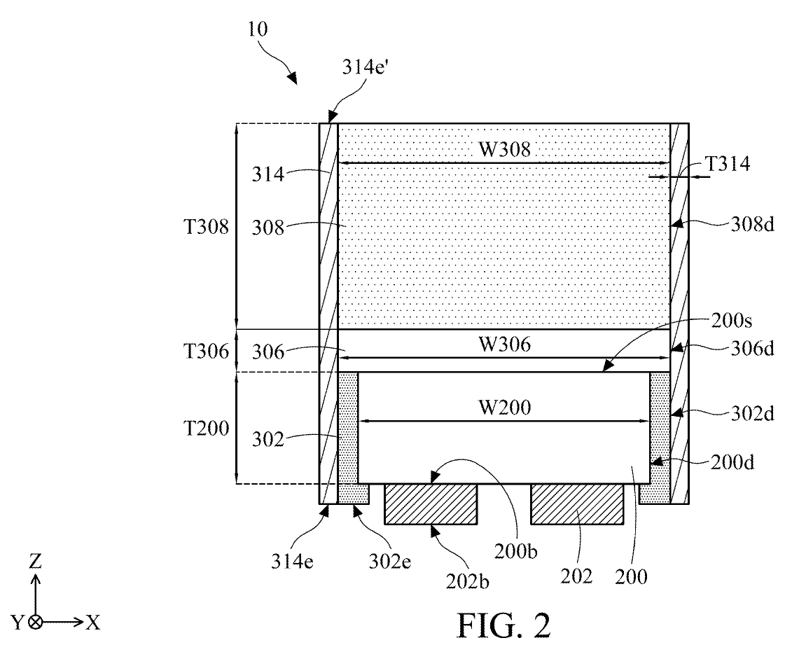

Please refer to FIG. 2, which is a cross-sectional schematic diagram illustrating an optical package 10 in accordance with some embodiments of the present disclosure. It should be understood that, for the sake of clarity, some elements of the optical package 10 may be omitted in the drawings, and only some elements are schematically illustrated. In accordance with some embodiments, additional features may be added to the optical package 10 described below. In accordance with some embodiments, some features of the optical package 10 described below may be replaced or omitted. It should be understood that elements that are identical or similar to those mentioned above will be denoted by the same or similar numerals, and their materials, formation methods, features and functions are the same or similar to those described above, and thus will not be repeated in the following description.

As shown in FIG. 2, the optical package 10 may include a light-emitting element 200, a wavelength conversion layer 308, and an adhesive layer 306. The wavelength conversion layer 308 may be disposed on the light-emitting element 200. The adhesive layer 306 may be disposed between the light-emitting element 200 and the wavelength conversion layer 308, and may be in contact with both the light-emitting element 200 and the wavelength conversion layer 308. Furthermore, the thickness T308 of the wavelength conversion layer 308 is greater than the thickness T200 of the light-emitting element 200. In accordance with some embodiments, the adhesive layer 306 is in direct contact with the light-emitting element 200 and the wavelength conversion layer 308.

As shown in FIG. 2, in particular, the thickness T308 of the wavelength conversion layer 308 being greater than the thickness T200 of the light-emitting element 200 may enhance the structural strength of the packaging structure.

As shown in FIG. 2, the light-emitting element 200 may be a light-emitting diode (LED), such as a mini light-emitting diode (mini LED), or a micro light-emitting diode (micro LED). The light-emitting element 200 may be a thin-film LED, which is a flip-chip type LED without a sapphire substrate. The light-emitting element 200 includes a first surface 200b and a second surface 200s opposite the first surface 200b. The light-emitting element 200 further includes an electrode 202 disposed on the first surface 200b. In accordance with some embodiments, the electrode 202 may be electrically connected to an external electronic component (not shown), which may include a printed circuit board (PCB), a driving component, or other suitable electronic components, but it is not limited thereto.

As shown in FIG. 2, the wavelength conversion layer 308 may convert the light generated by the light-emitting element 200 into light having a specific color or wavelength. The wavelength conversion layer 308 may include a matrix and one or more wavelength conversion materials dispersed in the matrix. In accordance with some embodiments, the wavelength conversion layer 308 may be a phosphor in glass (PiG) composite material.

As shown in FIG. 2, in accordance with some embodiments, the thickness T200 of the light-emitting element 200 may be in a range from 3 micrometers to 20 micrometers, such as 3 μm, 5 μm, 10 μm, 15 μm, 17 μm, or 20 μm. Specifically, the thickness T200 of the light-emitting element 200 is less than 20 μm, which may reduce lateral light loss of the light-emitting element 200. Moreover, in accordance with some embodiments, the thickness T308 of the wavelength conversion layer 308 may be in a range from 60 μm to 200 μm, such as 70 μm, 80 μm, 90 μm, 100 μm, 110 μm, 120 μm, 130 μm, 140 μm, 150 μm, 160 μm, 170 μm, 180 μm, or 190 μm. In accordance with some embodiments, the thickness T308 of the wavelength conversion layer 308 may be in a range from 80 μm to 180 μm, or from 90 μm to 160 μm, or from 100 μm to 140 μm. In accordance with some embodiments, the thickness T306 of the adhesive layer 306 may be in a range from 1 μm to 3 μm, such as 1.5 μm, 2 μm, or 2.5 μm.

As shown in FIG. 2, in accordance with some embodiments, the optical package 10 may further include a passivation layer 302, and the passivation layer 302 may cover the side surface 200d and the first surface 200b of the light-emitting element 200. Specifically, the passivation layer 302 may be conformally formed on portions of the first surface 200b and the side surface 200d of the light-emitting element 200. In accordance with some embodiments, the passivation layer 302 may not contact the electrode 202. In other words, the passivation layer 302 may extend onto the first surface 200b but is spaced apart from the electrode 202 by a distance. In accordance with some embodiments, the passivation layer 302 may extend onto the first surface 200b and contact the electrode 202. In accordance with some embodiments, an end portion 302e of the passivation layer 302 may not be aligned with the first surface 200b of the light-emitting element 200. For example, the end portion 302e of the passivation layer 302 may protrude beyond the first surface 200b of the light-emitting element 200. In accordance with some embodiments, along the normal direction of the light-emitting element 200 (e.g., the Z direction in the drawings), the end portion 302e of the passivation layer 302 is located between the first surface 200b of the light-emitting element 200 and the surface 202b of the electrode 202, and the surface 202b of the electrode 202 is a surface facing away from the light-emitting element 200. In accordance with some embodiments, the side surface 308d of the wavelength conversion layer 308, the side surface 306d of the adhesive layer 306, and the side surface 302d of the passivation layer 302 are aligned with each other.

As shown in FIG. 2, furthermore, in accordance with some embodiments, the optical package 10 may further include a light-modulating structure 314, and the light-modulating structure 314 surrounds the light-emitting element 200, the wavelength conversion layer 308, and the adhesive layer 306. The light-modulating structure 314 may contact the wavelength conversion layer 308 and the adhesive layer 306. In accordance with some embodiments, the light-modulating structure 314 may directly contact the wavelength conversion layer 308 and the adhesive layer 306. In accordance with some embodiments, the light-modulating structure 314 may also contact the side surface 302d of the passivation layer 302. In accordance with some embodiments, the light-modulating structure 314 may also directly contact the side surface 302d of the passivation layer 302. In accordance with some embodiments, an end portion 314e of the light-modulating structure 314 is aligned with the end portion 302e of the passivation layer 302. In accordance with some embodiments, the end portion 314e of the light-modulating structure 314 is not aligned with the first surface 200b of the light-emitting element 200. For example, the end portion 314e may protrude beyond the first surface 200b. In accordance with some embodiments, along the normal direction of the light-emitting element 200 (e.g., the Z direction in the drawing), the end portion 314e of the light-modulating structure 314 is located between the first surface 200b of the light-emitting element 200 and the surface 202b of the electrode 202, and the surface 202b of the electrode 202 is a surface facing away from the light-emitting element 200. Moreover, in accordance with some embodiments, another end portion 314e’ of the light-modulating structure 314 may be coplanar with the exposed surface of the wavelength conversion layer 308. In accordance with some embodiments, the width W200 of the light-emitting element 200 is less than the width W306 of the adhesive layer 306, and the width W200 of the light-emitting element 200 is less than the width W308 of the wavelength conversion layer 308.

As shown in FIG. 2, in particular, in the optical package 10, there is no substrate structure between the light-emitting element 200 and the wavelength conversion layer 308. For example, there is no sapphire substrate typically provided in conventional packaging structures situated between the light-emitting element 200 and the wavelength conversion layer 308. It is worth noting that packaging efficiency decreases as the side-wall height of the packaging structure increases. Since no substrate structure is provided between the light-emitting element 200 and the wavelength conversion layer 308, the overall thickness of the optical package 10 is reduced, thereby improving the packaging efficiency of the light-emitting element 200. Specifically, compared to a conventional packaging structure that includes a sapphire substrate (e.g., a sapphire substrate between the light-emitting element and the wavelength conversion layer), the thinned optical package 10 disclosed herein may provide an improvement in packaging efficiency, for example about 11%. As such, the performance and optical quality of the optical package 10 may be enhanced. In accordance with some embodiments, the ratio of the thickness T200 of the light-emitting element 200 to the thickness T308 of the wavelength conversion layer 308 may be between 1/75 and 1/5, such as 1/75, 1/50, 1/25, 1/10, or 1/5. In accordance with some embodiments, the ratio of the thickness T200 of the light-emitting element 200 to the thickness T308 of the wavelength conversion layer 308 may be between 1/50 and 1/10. In accordance with some embodiments, the ratio of the thickness T314 of the light-modulating structure 314 to the thickness T308 of the wavelength conversion layer 308 may be between 1/150,000 and 1/5, such as 1/150,000, 1/100,000, 1/50,000, 1/10,000, 1/5,000, 1/1,000, 1/100, 1/50, 1/10, or 1/5, enabling effective reduction of cross-talk between LED pixels, thereby improving light-emitting efficiency and optical quality. In accordance with some embodiments, the ratio of the thickness T314 of the light-modulating structure 314 to the thickness T308 of the wavelength conversion layer 308 may be between 1/100,000 and 1/50. In accordance with some embodiments, the ratio of the thickness T314 of the light-modulating structure 314 to the thickness T308 of the wavelength conversion layer 308 may be between 1/50,000 and 1/100. In accordance with some embodiments, the ratio of the thickness T314 of the light-modulating structure 314 to the thickness T308 of the wavelength conversion layer 308 may be between 1/10,000 and 1/1,000. In accordance with some embodiments, the ratio of the thickness T200 of the light-emitting element 200 to the sum of the thickness T308 of the wavelength conversion layer 308, the thickness T306 of the adhesive layer 306 and the thickness T200 of the light-emitting element 200 (i.e., thickness T200/(thickness T308 + thickness T306 + thickness T200)) may be between 1/200 and 1/5, such as 1/200, 1/150, 1/100, 1/50, 1/10, or 1/5, effectively reducing the overall thickness and volume of the optical package 10, enabling a thinner adaptive driving beam (ADB) system, and effectively decreasing cross-talk between LED pixels. In accordance with some embodiments, the ratio of the thickness T200 of the light-emitting element 200 to the sum of the thickness T308 of the wavelength conversion layer 308, the thickness T306 of the adhesive layer 306 and the thickness T200 of the light-emitting element 200 may be between 1/150 and 1/10. In accordance with some embodiments, the ratio of the thickness T200 of the light-emitting element 200 to the sum of the thickness T308 of the wavelength conversion layer 308, the thickness T306 of the adhesive layer 306 and the thickness T200 of the light-emitting element 200 may be between 1/100 and 1/50.

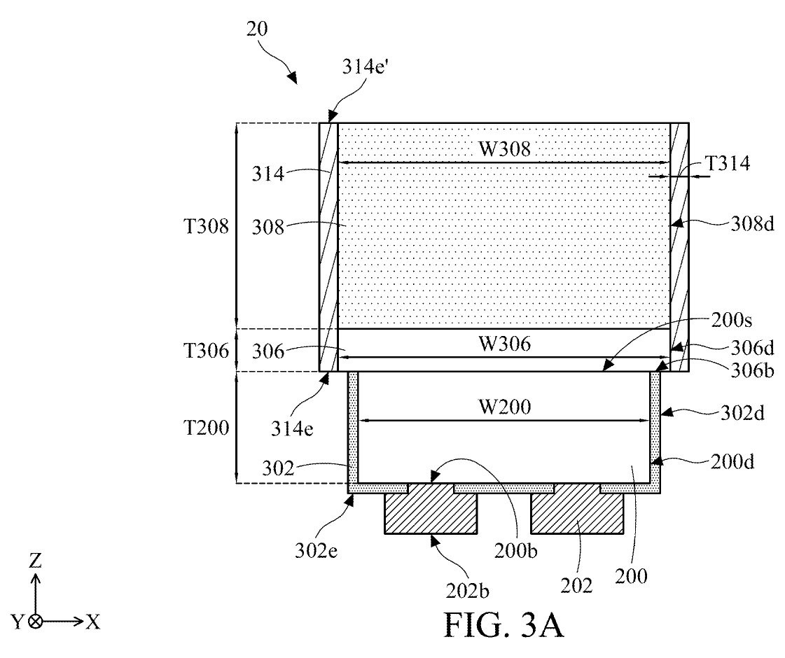

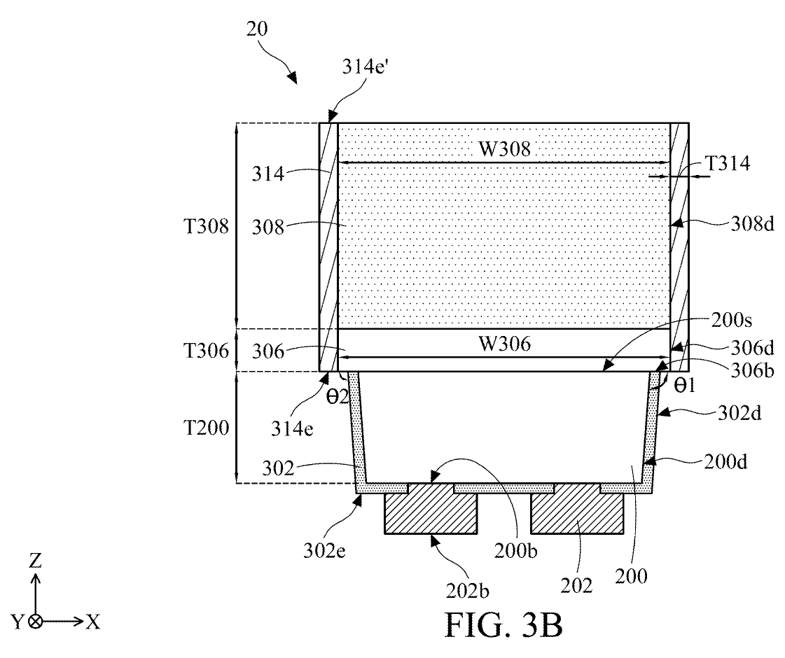

Please refer to FIG. 3A, which is a cross-sectional schematic diagram illustrating an optical package 20 in accordance with some other embodiments of the present disclosure. It should be understood that, for the sake of clarity, some elements of the optical package 20 may be omitted in the drawings, and only some elements are schematically illustrated. In accordance with some embodiments, additional features may be added to the optical package 20 described below. In accordance with some embodiments, some features of the optical package 20 described below may be replaced or omitted. It should be understood that elements that are identical or similar to those mentioned above will be denoted by the same or similar numerals, and their materials, formation methods, features and functions are the same or similar to those described above, and thus will not be repeated in the following description.

As shown in FIG. 3A, the optical package 20 is substantially similar to the optical package 10. Compared to the optical package 10, the light-modulating structure 314 of optical package 20 extends onto the side surface 308d of the wavelength conversion layer 308 and the side surface 306d of the adhesive layer 306, but does not extend to the side surface 200d of the light-emitting element 200 and the side surface 302d of the passivation layer 302. In this embodiment, the end portion 314e of the light-modulating structure 314 is not aligned with the end portion 302e of the passivation layer 302, and the end portion 314e of the light-modulating structure 314 is aligned with the second surface 200s of the light-emitting element 200. In this embodiment, the passivation layer 302 is disposed on the side surface 200d and the first surface 200b of the light-emitting element 200 and on the first surface 306b of the adhesive layer 306, and a portion of the passivation layer 302 may be disposed between the light-emitting element 200 and the electrode 202. In accordance with some embodiments, the electrode 202 penetrates the passivation layer 302 to electrically contact the light-emitting element 200. In accordance with some embodiments, the width W200 of the light-emitting element 200 is less than the width W306 of the adhesive layer 306, and the width W200 of the light-emitting element 200 is less than the width W308 of the wavelength conversion layer 308. Additionally, as shown in FIG. 3B, in accordance with some embodiments, the side surface 200d of the light-emitting element 200 is inclined such that an angle θ1 between the side surface 200d of the light-emitting element 200 and the first surface 306b of the adhesive layer 306 is greater than 90 degrees, for example between 90 degrees and 150 degrees. In accordance with some embodiments, the angle θ1 may be 95 degrees, 100 degrees, 105 degrees, 110 degrees, 115 degrees, 120 degrees, 125 degrees, 130 degrees, 135 degrees, 140 degrees, or 145 degrees. In accordance with some embodiments, the angle θ1 is an obtuse angle. In accordance with some embodiments, the side surface 302d of the passivation layer 302 on the side surface 200d of the light-emitting element 200 is inclined such that an angle θ2 between the side surface 302d of the passivation layer 302 and the first surface 306b of the adhesive layer 306 is greater than 90 degrees, for example between 90 degrees and 150 degrees. In accordance with some embodiments, the angle θ2 may be 95 degrees, 100 degrees, 105 degrees, 110 degrees, 115 degrees, 120 degrees, 125 degrees, 130 degrees, 135 degrees, 140 degrees, or 145 degrees. In accordance with some embodiments, the angle θ2 is an obtuse angle. In accordance with some embodiments, the angle θ1 is greater than or equal to the angle θ2.

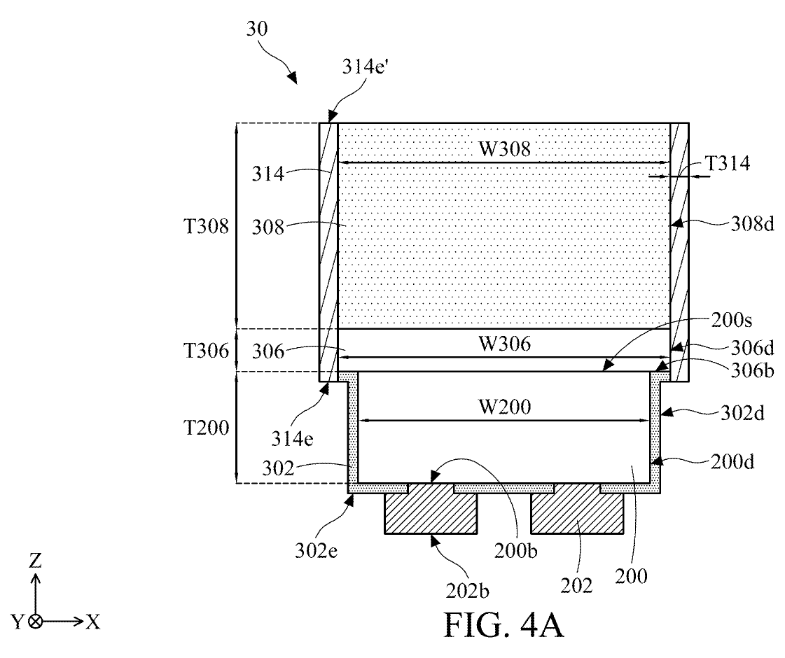

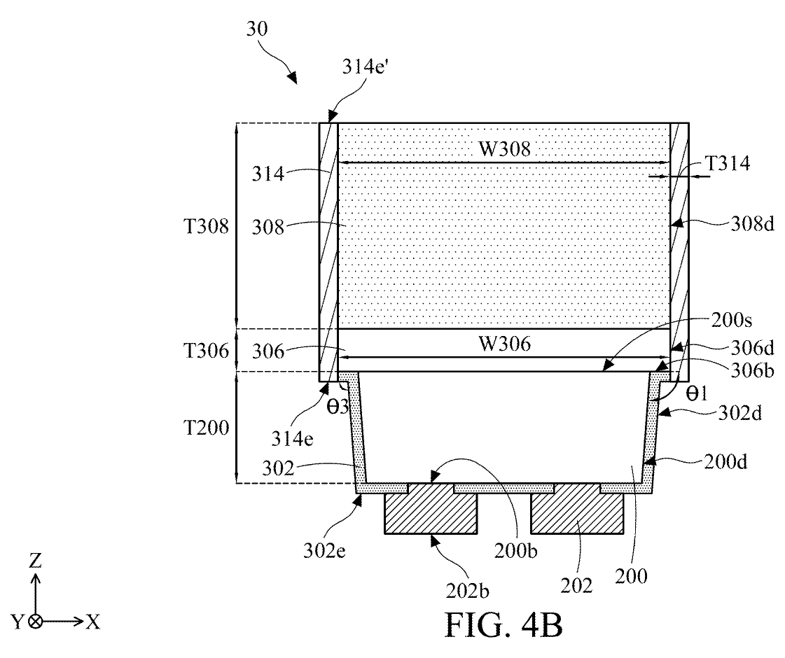

Please refer to FIG. 4A, which is a cross-sectional schematic diagram illustrating an optical package 30 in accordance with some other embodiments of the present disclosure. It should be understood that, for the sake of clarity, some elements of the optical package 30 may be omitted in the drawings, and only some elements are schematically illustrated. In accordance with some embodiments, additional features may be added to the optical package 30 described below. In accordance with some embodiments, some features of the optical package 30 described below may be replaced or omitted.

As shown in FIG. 4A, the optical package 30 is substantially similar to the optical package 10. Compared to the optical package 10, the light-modulating structure 314 of optical package 30 extends onto the side surface 308d of the wavelength conversion layer 308 and the side surface 306d of the adhesive layer 306, and partially extends onto the side surface 302d of the passivation layer 302, but does not extend to the end portion 302e of the passivation layer 302. In this embodiment, the end portion 314e of the light-modulating structure 314 is not aligned with the second surface 200s of the light-emitting element 200; along the normal direction (e.g., the Z direction in the drawing), the end portion 314e protrudes beyond the second surface 200s of the light-emitting element 200. In this embodiment, one end of the passivation layer 302 may contact both the adhesive layer 306 and the light-modulating structure 314. Furthermore, in this embodiment, the passivation layer 302 is disposed on the side surface 200d and the first surface 200b of the light emitting element 200 and a portion of the first surface 306b of the adhesive layer 306, and a portion of the passivation layer 302 may be disposed between the light emitting element 200 and the electrode 202. In accordance with some embodiments, the electrode 202 penetrates the passivation layer 302 to electrically contact the light-emitting element 200. In accordance with some embodiments, the width W200 of the light-emitting element 200 is less than the width W306 of the adhesive layer 306 and less than the width W308 of the wavelength conversion layer 308. The width W308 of the wavelength conversion layer 308 is substantially equal to the width W306 of the adhesive layer 306. Additionally, as shown in FIG. 4B, in accordance with some embodiments, the side surface 200d of the light emitting element 200 is inclined such that an angle θ1 between the side surface 200d of the light emitting element 200 and the first surface 306b of the adhesive layer 306 is greater than 90 degrees, for example between 90 degrees and 150 degrees. In accordance with some embodiments, the angle θ1 may be 95 degrees, 100 degrees, 105 degrees, 110 degrees, 115 degrees, 120 degrees, 125 degrees, 130 degrees, 135 degrees, 140 degrees, or 145 degrees. In accordance with some embodiments, the angle θ1 is an obtuse angle. In accordance with some embodiments, the side surface 302d of the passivation layer 302 on the side surface 200d is inclined such that an angle θ3 between the side surface 302d of the passivation layer 302 and the first surface 306b of the adhesive layer 306 is greater than 90 degrees, for example between 90 degrees and 150 degrees. In accordance with some embodiments, the angle θ3 may be 95 degrees, 100 degrees, 105 degrees, 110 degrees, 115 degrees, 120 degrees, 125 degrees, 130 degrees, 135 degrees, 140 degrees, or 145 degrees. In accordance with some embodiments, the angle θ3 is an obtuse angle. In accordance with some embodiments, the angle θ1 is greater than or equal to the angle θ3.

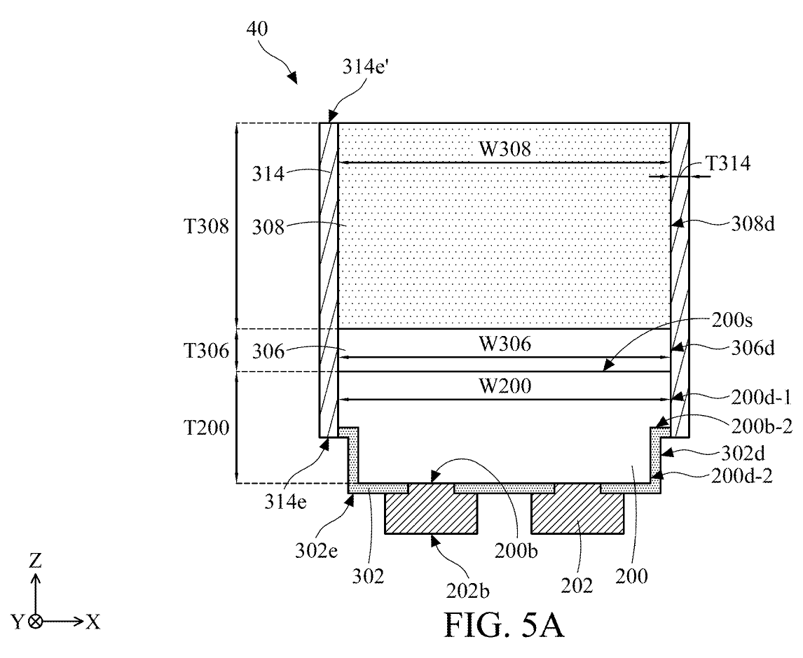

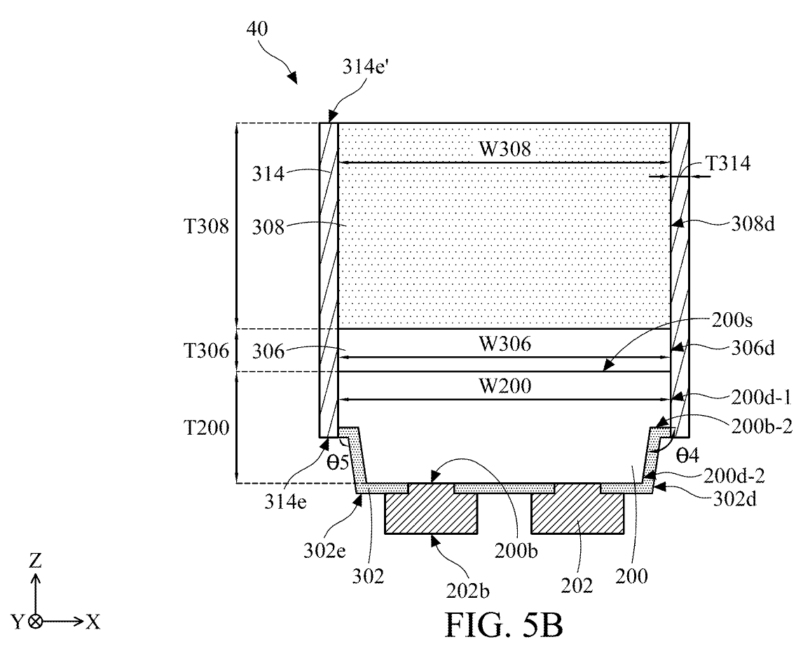

Please refer to FIG. 5A, which is a cross-sectional schematic diagram illustrating an optical package 40 in accordance with some other embodiments of the present disclosure. It should be understood that, for the sake of clarity, some elements of the optical package 40 may be omitted in the drawings, and only some elements are schematically illustrated. In accordance with some embodiments, additional features may be added to the optical package 40 described below. In accordance with some embodiments, some features of the optical package 40 described below may be replaced or omitted.

As shown in FIG. 5A, the optical package 40 is substantially similar to the optical package 10. Compared to the optical package 10, the light-modulating structure 314 of optical package 40 extends onto the side surface 308d of the wavelength conversion layer 308 and the side surface 306d of the adhesive layer 306, as well as the first side surface 200d 1 of the light-emitting element 200, and partially extends onto the side surface 302d of the passivation layer 302, but does not extend to the end portion 302e of the passivation layer 302. Specifically, in this embodiment, the light-emitting element 200 may have the first side surface 200d-1 and the second side surface 200d-2 that are not aligned with each other. For example, the first side surface 200d-1 and the second side surface 200d-2 may be stepped. In this embodiment, the end portion 314e of the light-modulating structure 314 is not aligned with the end portion 302e of the passivation layer 302; along the normal direction (e.g., the Z direction in the drawing), the end portion 314e may be disposed between the second surface 200s and the first surface 200b of the light-emitting element 200. Furthermore, in this embodiment, the passivation layer 302 is disposed on the second side surface 200d 2 and the first surface 200b of the light-emitting element 200, and a portion of the passivation layer 302 may be disposed between the light-emitting element 200 and the electrode 202. In accordance with some embodiments, the light emitting element 200 includes a third surface 200b-2 located between the first side surface 200d-1 and the second side surface 200d-2.

As shown in FIG. 5A, in accordance with some embodiments, the electrode 202 penetrates the passivation layer 302 to electrically contact the light-emitting element 200. In accordance with some embodiments, the width W200 of the light-emitting element 200 is less than the width W306 of the adhesive layer 306 and less than the width W308 of the wavelength conversion layer 308. The width W308 of the wavelength conversion layer 308 is substantially equal to the width W306 of the adhesive layer 306. Additionally, as shown in FIG. 5B, in accordance with some embodiments, the second side surface 200d 2 of the light-emitting element 200 is inclined such that an angle θ4 between the second side surface 200d 2 of the light-emitting element 200 and the third surface 200b 2 of the light-emitting element 200 is greater than 90 degrees, for example between 90 degrees and 150 degrees. In accordance with some embodiments, the angle θ4 may be 95 degrees, 100 degrees, 105 degrees, 110 degrees, 115 degrees, 120 degrees, 125 degrees, 130 degrees, 135 degrees, 140 degrees, or 145 degrees. In accordance with some embodiments, the angle θ4 is an obtuse angle.

As shown in FIG. 5B, in accordance with some embodiments, the passivation layer 302 on the second side surface 200d 2 of the light-emitting element 200 is inclined such that an angle θ5 between the side surface 302d of the passivation layer 302 and the passivation layer 302 on the third surface 200b-2 of the light-emitting element 200 is greater than 90 degrees, for example between 90 degrees and 150 degrees. In accordance with some embodiments, the angle θ5 may be 95 degrees, 100 degrees, 105 degrees, 110 degrees, 115 degrees, 120 degrees, 125 degrees, 130 degrees, 135 degrees, 140 degrees, or 145 degrees. In accordance with some embodiments, the angle θ5 is an obtuse angle. In accordance with some embodiments, the angle θ4 is greater than or equal to the angle θ5.

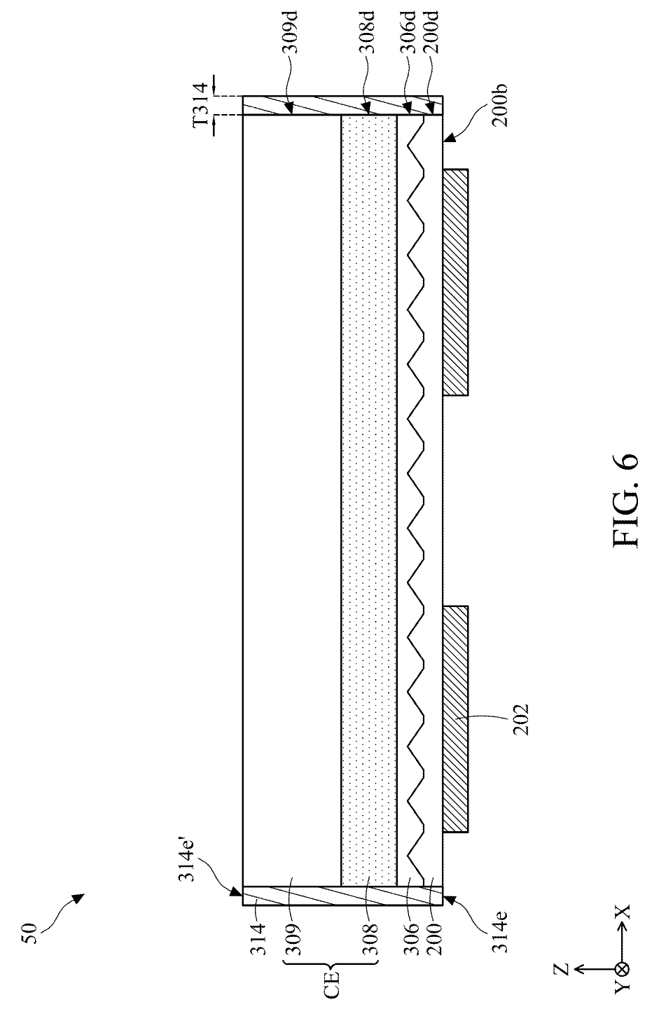

Please refer to FIG. 6, which is a cross-sectional schematic diagram illustrating an optical package 50 in accordance with some other embodiments of the present disclosure. It should be understood that, for the sake of clarity, some elements of the optical package 50 may be omitted in the drawings, and only some elements are schematically illustrated. In accordance with some embodiments, additional features may be added to the optical package 50 described below. In accordance with some embodiments, some features of the optical package 50 described below may be replaced or omitted.

As shown in FIG. 6, the optical package 50 may include the light-emitting element 200, a wavelength conversion element CE, the adhesive layer 306, and the light-modulating structure 314. The wavelength conversion element CE may be disposed on the light-emitting element 200. The adhesive layer 306 may be disposed between the light-emitting element 200 and the wavelength conversion element CE, and the adhesive layer 306 may contact both the light-emitting element 200 and the wavelength conversion element CE. Specifically, the wavelength conversion element CE may include a supporting layer 309 and the wavelength conversion layer 308. The wavelength conversion layer 308 is disposed between the supporting layer 309 and the adhesive layer 306. The adhesive layer 306 is disposed between the light-emitting element 200 and the wavelength conversion layer 308, and the adhesive layer 306 may contact both the light-emitting element 200 and the wavelength conversion layer 308. In accordance with some embodiments, the adhesive layer 306 may directly contact the light-emitting element 200 and the wavelength conversion layer 308. In accordance with some embodiments, the side surface 200d of the light-emitting element 200, the side surfaces of the wavelength conversion element CE (including the side surface 308d of the wavelength conversion layer 308 and the side surface 309d of the supporting layer 309), and the side surface 306d of the adhesive layer 306 may be coplanar with each other. The side surface 200d of the light-emitting element 200, the side surfaces of the wavelength conversion element CE (including the side surface 308d of the wavelength conversion layer 308 and the side surface 309d of the supporting layer 309), and the side surface 306d of the adhesive layer 306 may be continuous cut surfaces.

As shown in FIG. 6, the light-modulating structure 314 may surround the light-emitting element 200, the wavelength conversion element CE and the adhesive layer 306, and may contact both the wavelength conversion element CE and the adhesive layer 306. In accordance with some embodiments, the light-modulating structure 314 may directly contact the supporting layer 309, the wavelength conversion layer 308, and the adhesive layer 306. In accordance with some embodiments, the end portion 314e of the light-modulating structure 314 is aligned with the first surface 200b of the light-emitting element 200. In accordance with some embodiments, another end portion 314e’ of the light-modulating structure 314 may be aligned with the exposed surface of the supporting layer 309 of the wavelength conversion element CE. In accordance with some embodiments, the thickness T314 of the light-modulating structure 314 may be less than 10 µm, for example 9µm, 8µm, 7µm, 6µm, 5µm, 4µm, 3µm, 2µm, or 1 µm. In particular, when the thickness T314 is less than 10 µm, the optical package 50 enables closer spacing of light sources in a module; conversely, if the thickness T314 is greater than 10 µm, the spacing of light sources in the module will be larger, so that the dark band of the light spot will also be larger.

As shown in FIG. 6, in accordance with some embodiments, the roughness of the side surface 200d of the light-emitting element 200, the side surfaces of the wavelength conversion element CE (including the side surface 308d of the wavelength conversion layer 308 and the side surface 309d of the supporting layer 309) and the side surface 306d of the adhesive layer 306 are all less than 1 µm. It is noted that, when the roughness of the side surface 200d of the light-emitting element 200, the side surfaces of the wavelength conversion element CE (including the side surface 308d of the wavelength conversion layer 308 and the side surface 309d of the supporting layer 309) and the side surface 306d of the adhesive layer 306 exceeds 1 µm, the specular reflectance of the light-modulating structure 314 formed thereon may be reduced.

As shown in FIG. 6, in accordance with some embodiments, the supporting layer 309 of the wavelength conversion element CE may include glass, quartz, sapphire, ceramic, other suitable materials, or a combination thereof, but it is not limited thereto.

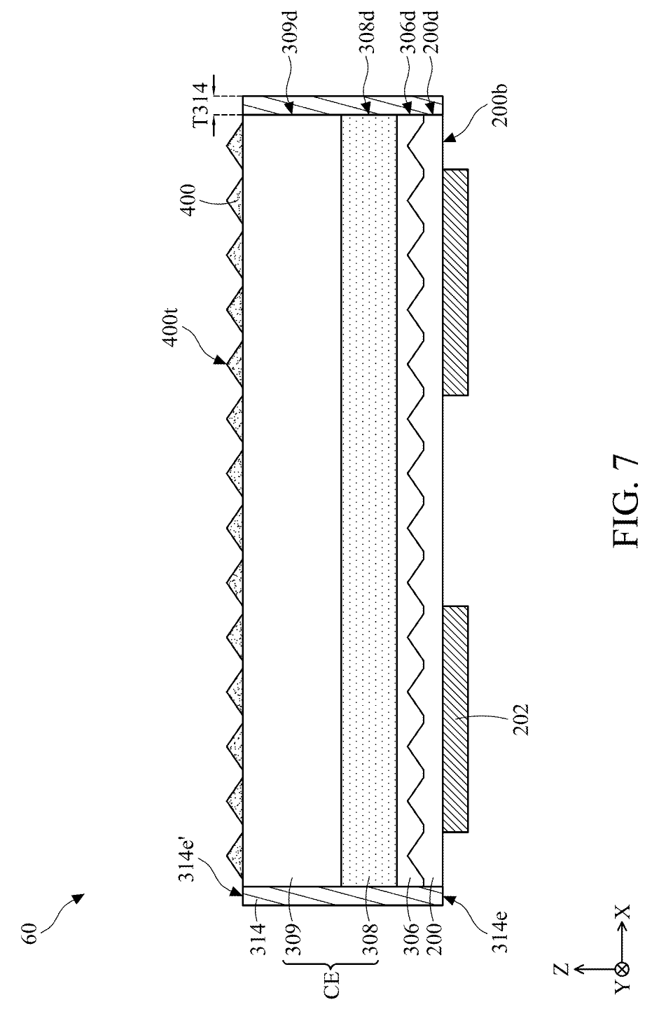

Please refer to FIG. 7, which is a cross-sectional schematic diagram illustrating an optical package 60 in accordance with some other embodiments of the present disclosure. It should be understood that, for the sake of clarity, some elements of the optical package 60 may be omitted in the drawings, and only some elements are schematically illustrated. In accordance with some embodiments, additional features may be added to the optical package 60 described below. In accordance with some embodiments, some features of the optical package 60 described below may be replaced or omitted.

As shown in FIG. 7, the optical package 60 is substantially similar to the optical package 50. Compared to the optical package 50, the optical package 60 further includes a patterned structure 400 disposed on the supporting layer 309 of the wavelength conversion element CE. In accordance with some embodiments, the patterned structure 400 may contact the supporting layer 309. Specifically, the top portion 400t of the patterned structure 400 is higher than the end portion 314e’ of the light-modulating structure 314. In other words, compared to the end portion 314e’ of the light-modulating structure 314, the top portion 400t of the patterned structure 400 is protruding. It is noted that, if the top portion 400t of the patterned structure 400 is not higher than the end portion 314e’ of the light-modulating structure 314, the light-emitting efficiency of the optical package 60 may be reduced.

As shown in FIG. 7, in accordance with some embodiments, the material of the patterned structure 400 may include polyimide (PI), silicone, epoxy, other suitable materials, or a combination thereof, but it is not limited thereto.

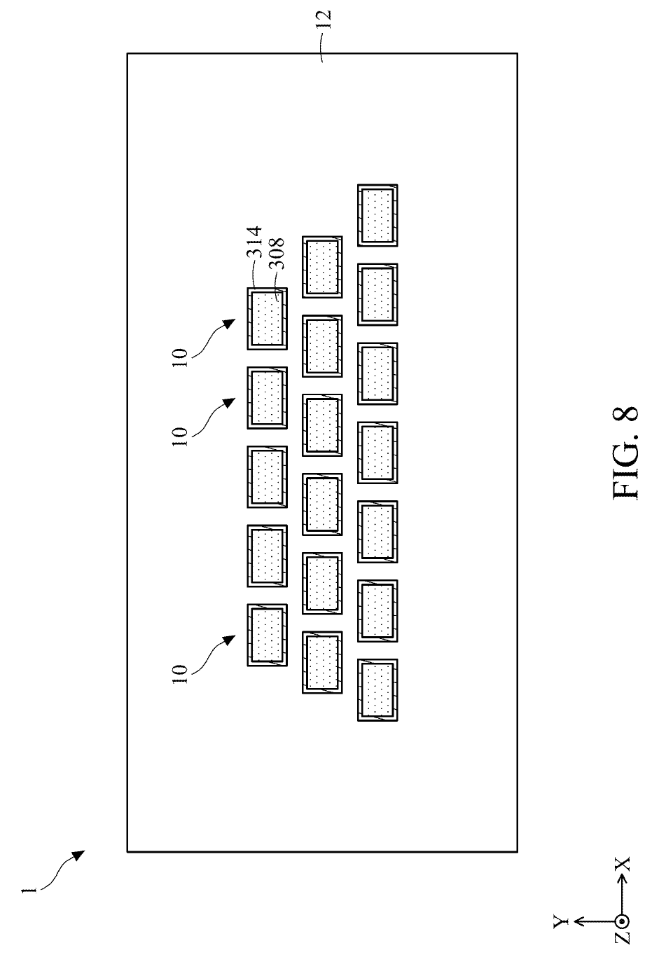

Please refer to FIG. 8, which is a top-view schematic diagram illustrating an electronic device 1 including the optical package 10 in accordance with some embodiments of the present disclosure. It should be understood that, for the sake of clarity, some elements of the electronic device 1 may be omitted in the drawings, and only some elements are schematically illustrated. In accordance with some embodiments, additional features may be added to the electronic device 1 described below. In accordance with some embodiments, some features of the electronic device 1 described below may be replaced or omitted. Moreover, FIG. 8 takes the electronic device 1 including the optical package 10 as an example. In accordance with some other embodiments, the electronic device 1 may also include the optical package 20, the optical package 30, the optical package 40, the optical package 50, the optical package 60 or a combination thereof.

As shown in FIG. 8, the electronic device 1 may include a substrate 12 and a plurality of optical packages 10 arranged on the substrate 12. In the optical package 10, the light-modulating structure 314 may surround the wavelength conversion layer 308. In accordance with some embodiments, the light-modulating structure 314 may surround the wavelength conversion layer 308 in a closed manner. In accordance with some embodiments, the light-modulating structure 314 may have a square or rectangular shape when viewed from a top view. In accordance with some embodiments, the substrate 12 may include driving components (not shown), and the optical packages may be electrically connected to the driving components. The driving component may include an active driving component, a passive driving component, or a combination thereof. The active driving component may include a thin-film transistor (TFT), but it is not limited thereto. Furthermore, in the embodiment where the driving component is a passive driving component, the driving component may be controlled by, for example, an integrated circuit (IC) or a microchip, but the present disclosure is not limited thereto. In accordance with some embodiments, the substrate 12 may be a printed circuit board (PCB), but it is not limited thereto. Furthermore, in accordance with some embodiments, the plurality of optical packages 10 may be arranged in a trapezoidal shape, but it is not limited thereto.

As shown in FIG. 8, in accordance with some embodiments, the electronic device 1 may be an adaptive driving beam (ADB) headlamp system. In other words, the optical package 10 may be applied in a multi-pixel configuration for ADB systems. Specifically, each optical packaging structure 10 may independently sense ambient light and adjust its emission brightness accordingly. The optical package 10 can reduce cross-talk between LED pixels, improving light-emitting efficiency and optical quality.

To summarize the above, in accordance with some embodiments of the present disclosure, the provided method for manufacturing an optical package employs a laser lift-off (LLO) process and an adhesive bonding process to bond a light-emitting element with a wavelength conversion layer. Through such a configuration, the light-emitting element and the wavelength conversion layer may be joined without a substrate structure (e.g., a sapphire substrate) therebetween. This can improve the packaging efficiency of the light-emitting element and effectively enhance the optical performance of the optical package.

Although some embodiments of the present disclosure and their advantages have been described in detail, it should be understood that various changes, substitutions and alterations can be made herein without departing from the spirit and scope of the present disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An optical package, comprising:
a light-emitting element, having a first thickness, a first surface and a second surface opposite the first surface;
a wavelength conversion layer, having a second thickness, disposed on the light-emitting element; and
an adhesive layer, disposed between the light-emitting element and the wavelength conversion layer, and contacting with the light-emitting element and the wavelength conversion layer,
wherein the second thickness is greater than the first thickness.

2. The optical package of claim 1, wherein the first thickness is ranged between 3 micrometers and 20 micrometers.

3. The optical package of claim 1, wherein the second thickness is ranged between 60 micrometers and 200 micrometers.

4. The optical package of claim 1, further comprising:
a light-modulating structure, surrounding the light-emitting element, the wavelength conversion layer, and the adhesive layer, and contacting with the wavelength conversion layer and the adhesive layer.

5. The optical package of claim 4, wherein the light-modulating structure comprises an omni-directional reflector (ODR) structure, a distributed Bragg reflector (DBR) structure, or a combination thereof.

6. The optical package of claim 4, wherein the light-modulating structure has a first end portion that is not aligned with the first surface.

7. The optical package of claim 6, wherein the first end portion protrudes beyond the first surface of the light-emitting element.

8. The optical package of claim 1, wherein the light-emitting element comprises an electrode disposed on the first surface.

9. The optical package of claim 8, further comprising:
a passivation layer, having a second end portion, and covering the first surface.

10. The optical package of claim 9, wherein the wavelength conversion layer has a first side surface, the adhesive layer has a second side surface coplanar with first side surface.

11. The optical package of claim 9, wherein the second end portion is not aligned with the first surface.

12. The optical package of claim 11, wherein the second end portion protrudes beyond the first surface.

13. The optical package of claim 1, wherein the light-emitting element and the wavelength conversion layer are not separated by a sapphire substrate.
